(19) United States
(12) Patent Application Publication
(10) Pub. No.: US 2013/0068707 A1
(43) Pub. Date: Mar. 21, 2013

(54) MOUNTING DEVICE FOR OPTICAL DISK DRIVE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/267,902

(22) Filed: Oct. 7, 2011

(30) Foreign Application Priority Data
Sep. 16, 2011 (CN) 201110275063.4

(51) Int. Cl. H05K 7/18

(52) U.S. Cl. 211/26

(57) ABSTRACT

A mounting device for mounting an optical disk drive (ODD) includes a rack and a fixing member. The rack defines an opening in a front side through which the ODD extends into the rack. A blocking plate is formed at a rear end of the rack to block a back end of the ODD. Two bars are formed between the opening and the blocking portion to sandwich the ODD. The fixing member is pivotally mounted to a side of the opening to block a front end of the ODD.

### CROSS-REFERENCE OF RELATED APPLICATIONS

Relevant subject matter is disclosed in a pending U.S. patent application, titled “MOUNTING DEVICE FOR OPTICAL DISK DRIVE”, filed on Sep. 29, 2011, with the application Ser. No. 13/248,047, which is assigned to the same assignee as this patent application.

### BACKGROUND

1. Technical Field

The present disclosure relates to a device for mounting an optical disk drive.

2. Description of Related Art

An electronic device, such as a computer, is generally equipped with data storage devices, such as optical disk drives. Mounting the storage device to the electronic device with screws is inefficient and always requires a tool, such as a screw drive, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device, together with an optical disk drive (ODD).

FIG. 2 is an enlarged view of the circled portion II of FIG. 1.

FIG. 3 is an isometric view of the mounting device of FIG. 1 in an assembled state.

FIG. 4 is similar to FIG. 3, but showing the mounting device in an unlocked state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

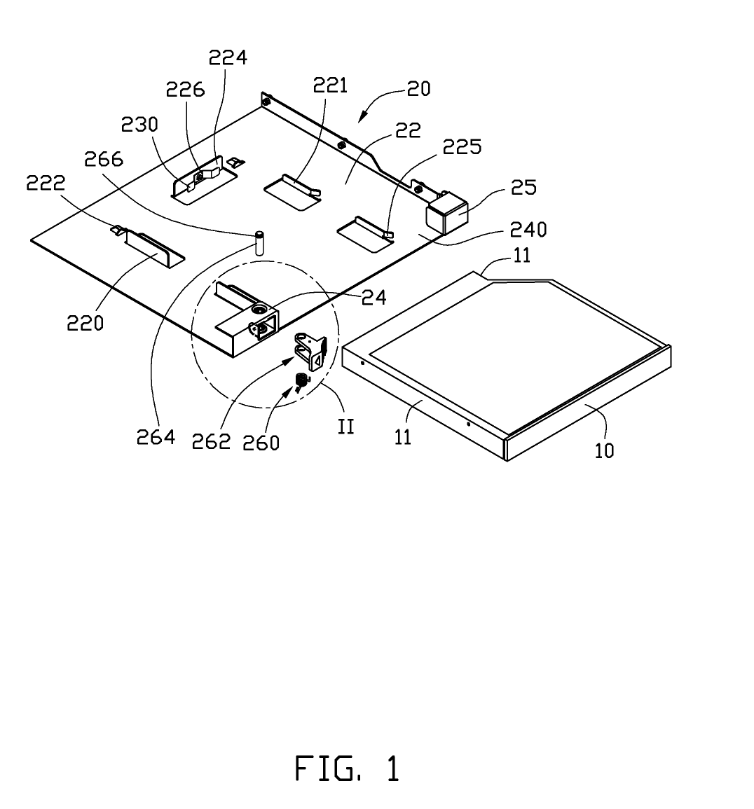

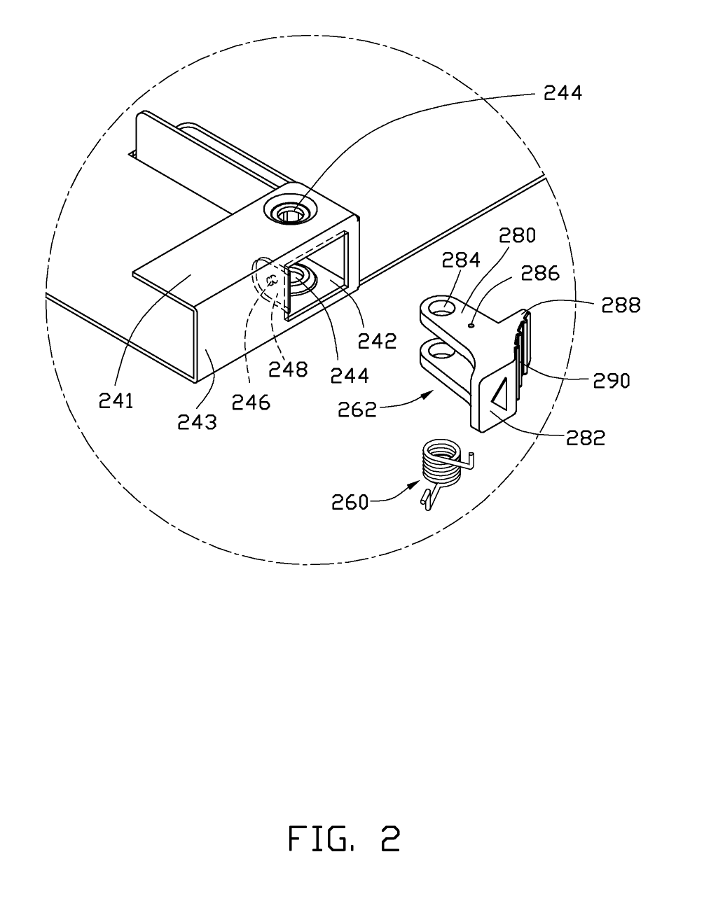

Referring to FIGS. 1 and 2, an exemplary embodiment of a mounting device for an optical disk drive (ODD) 10 includes a rack 20, a fixing member 262, a pole 264, and a torsion spring 260 with two feet (not labeled).

The ODD 10 includes two opposite sidewalls 11.

The rack 20 includes a bottom wall 22 and an opening 240 defined above the front side of the bottom wall. The rack 20 includes an installing member 24 and a block 25 formed at the bottom wall 22 beside the opening 240. A blocking plate 224 is formed at a rear portion of the bottom wall 22, corresponding to the opening 240. An elastic member 226 is mounted to a front side of the blocking plate 224. The elastic member 226 includes a connecting tab attached to the blocking plate 224, and two symmetrical urging tabs 230 slantingly extending forward from opposite ends of the connecting tab. Two blocking tabs 222 extend from the bottom wall 22, located beside the blocking plate 224 and in alignment with the blocking plates 224. A row of first bars 220 and a row of second bars 221 perpendicularly extend from the bottom wall 22 and are positioned between the blocking plate 224 and the opening 240. The first bars 220 are higher than the second bars 221. A guiding portion 225 extends slantingly and forward from each of the second bars 221.

The installing member 24 includes two horizontal side boards 241 and an end board 243 perpendicularly connected between the front side of the side boards 241. The two side boards 241 each define a through hole 244. The end board 243 defines an entry 242. A fixing tab 248 perpendicularly extends backward from a side of the entry 242 and defines a fixing hole 246. In this embodiment, the lower side board 241 is a portion of the bottom wall 22.

The fixing member 262 includes two parallel clamping boards 280, an operation portion 286 and a positioning projection 288 formed at the same ends of the clamping boards 280 extending in opposite direction. The clamping boards 280 each define an engaging hole 284. A fixing hole 286 is defined in one of the clamping board 280. An antiskid portion 290 is formed on the operation portion 286 for conveniently operating the operation portion 286.

A toothed portion 266 is formed on the circumference of an end of the pole 264.

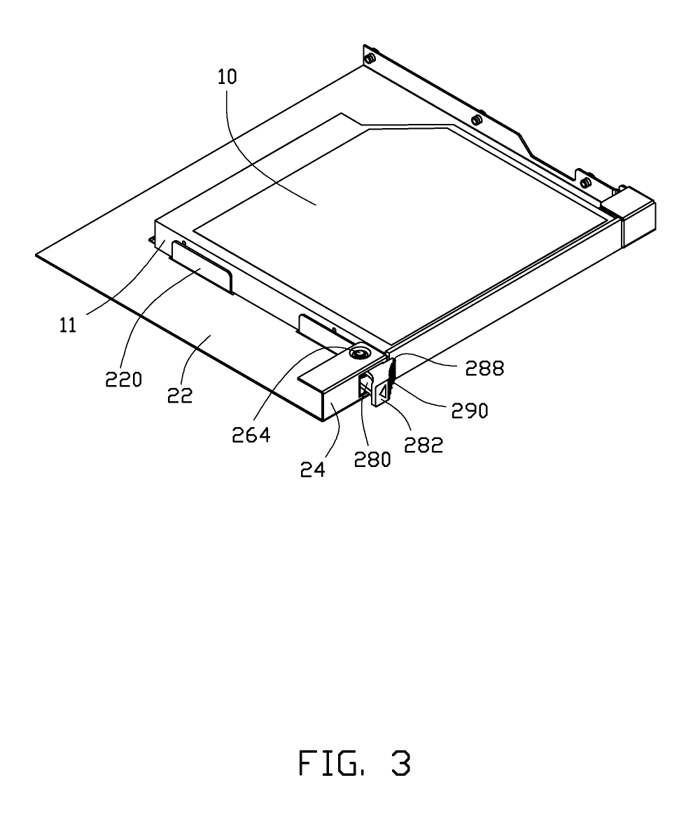

Referring to FIG. 3, in assembly, the torsion spring 260 is sandwiched between the clamping boards 280. One of the feet of the torsion spring 260 is engaged in the fixing hole 286. The fixing member 262 is received in the installing member 24 through the entry 242, and the other one of the feet of the torsion spring 260 is engaged in the fixing hole 246. The pole 264 extends through one of the through holes 244 away from the bottom wall 22, one of the engaging holes 284, the torsion spring 260, the other one of the engaging holes 284, and then is inserted into the other one of the through holes 244, until the toothed portion 266 is engaged in the through hole 244 away from the bottom wall 22, to pivotally mount the fixing member 262 to the installing member 24. The positioning projection 288 aligns with the opening 240.

In use, the operation portion 282 is operated to rotatably move the positioning projection 288 away from the opening 240 and deform the torsion spring 260. The ODD 10 is inserted into the rack 20 through the opening 240 and is sandwiched between the first and second bars 220 and 221, until the rear end of the ODD 10 presses the urging tabs 230 to contact the blocking plates 224. The operation portion 282 is then released, and the torsion spring 260 is restored to move the positioning projection 288 toward the opening 240 to block the front end of the ODD 10.

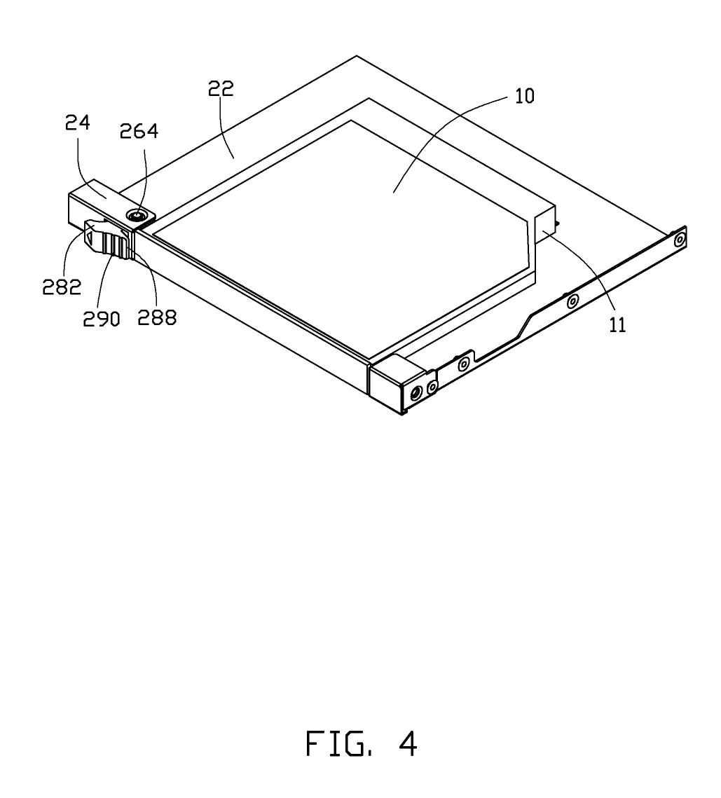

Referring to FIG. 4, in uninstall the ODD 10, the operation portion 282 is operated to move the positioning projection 288 away from the opening 240; and the urging tabs 230 are restored to move the ODD 10 out of the opening 240.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for fixing an optical disk drive (ODD), the mounting device comprising:
a rack comprising an opening defined in a front end thereof for accessing the ODD, a blocking plate formed at a rear end thereof to block a rear end of the ODD, two bars formed between the blocking plate and the opening to contact sidewalls of the ODD, and an installing member formed on a side of the opening; and
a fixing member pivotably mounted to the installing member to block a front end of the ODD.

2. The mounting device of claim 1, wherein an elastic member is attached to the blocking plate to resist against the rear end of the ODD.

3. The mounting device of claim 2, wherein the elastic member comprises a connecting tab attached to the blocking plate, and two symmetrical urging tabs slantingly extending from opposite ends of the connecting tab.

4. The mounting device of claim 1, wherein the rack further comprises a bottom wall, the blocking plate perpendicularly extends from the bottom wall; two blocking tabs extend from the bottom wall, located beside the blocking plate and in alignment with the blocking plate.

5. The mounting device of claim 4, further comprising a pole, wherein the installing member comprises two parallel side boards each defining a through hole, and an end board connected between the front side of the two side boards and defining an entry, the fixing member comprises two parallel clamping boards each defining an engaging hole, the clamping boards are sandwiched between the side boards through the entry, the pole extends through the through holes and the engaging holes to pivotably attach the fixing member to the installing member.

6. The mounting device of claim 5, further comprising a torsion spring with two feet, wherein a fixing tab extends rearward from a side of the entry and defines a fixing hole, one of the clamping boards defines a fixing hole, the torsion spring is fit about the pole and sandwiched between the clamping boards, the feet of the torsion spring are respectively engaged in the fixing holes.

7. The mounting device of claim 5, wherein the fixing member further comprises an operation portion and a positioning projection formed at ends of a same side of the clamping boards extending in opposite directions, the positioning projection is pivotable to block the front end of the ODD.

8. The mounting device of claim 7, wherein an antiskid portion is formed on the operation portion.

9. The mounting device of claim 5, wherein one of the side boards is a part of the bottom wall.

10. The mounting device of claim 9, wherein a toothed portion is formed on the circumference of the pole to accommodate with the through hole of the other one of the side boards.
